(19) United States
(12) Patent Application Publication
(10) Pub. No.: US 2008/0203410 A1
(43) Pub. Date: Aug. 28, 2008

(54) Methods for the Production of Luminescent Diode Chips and Luminescent Diode Chip

(75) Inventors: Herbert Brunner, Sinzing (DE); Dieter Eissler, Nittendorf (DE); Berthold Hahn, Hernau (DE); Volker Harle, Laaber (DE); Harald Jager, Regensburg (DE); Gertrud Krauter, Regensburg (DE); Gunter Waitl, Regensburg (DE)

Correspondence Address: FISH & RICHARDSON PC, P.O. BOX 1022, MINNEAPOLIS, MN, 55440-1022, US

(73) Assignee: OSRAM OPTO SEMICONDUCTORS GMBH, Regensburg (DE)

(21) Appl. No.: 11/576,057

(22) PCT Filed: Aug. 4, 2005
(86) PCT No.: PCT/DE2005/001382

§ 371 Date: Dec. 12, 2007

(30) Foreign Application Priority Data
Sep. 30, 2004 (DE) 102004047644.6
Dec. 15, 2004 (DE) 10 2004 060 358.8

(51) Int. Cl. H01L 33/00

(52) U.S. Cl. 257/98; 438/29; 257/E33.061

(57) ABSTRACT

The invention relates to a method of making LED chips provided with a luminescence conversion material containing at least one phosphor. In the method, a layer composite is prepared that includes an LED layer sequence for a multiplicity of LED chips and comprises on a main surface at least one electrical contact surface for each LED chip, for electrically connecting said chip. A layer of adhesion promoter is applied to the main surface and selectively removed from at least portions of the contact surfaces. At least one phosphor is then applied to the main surface. Alternatively, a luminescence conversion material is applied to the main surface and selectively removed from at least portions of the contact surfaces. The invention also relates to an LED chip provided with a luminescence conversion material.

The invention relates to a light-emitting diode (LED) chip provided with a luminescence conversion material containing at least one phosphor. The invention further relates to a method of making such LED chips.

In connection with optoelectronic components that emit electromagnetic radiation, it is known to encapsulate LED chips in a potting compound containing an admixture of a luminescence conversion material comprising at least one phosphor. The encapsulating is done for example by potting a housing cavity in which an LED chip is mounted, or by overmolding a leadframe-mounted LED chip via transfer molding.

The phosphor can be excited by a primary electromagnetic radiation emitted by the LED chip, and emits a secondary radiation, the wavelength ranges of the primary radiation and the secondary radiation being different. A desired resultant color locus of the component can be obtained for example by adjusting the mixing ratio of the primary and secondary radiations.

When such potting compounds are used, color variations can occur as a result of inhomogeneous distribution of the phosphor in the potting compound, due for example to settling of the phosphor particles. In addition, there are production tolerances in terms of the meterability of the potting compound, the heights of LED chips and/or the ability of the LED chips to be positioned in the cavity of an injection mold. This can lead to significant variations in the amount of potting compound disposed after the LED chip in m emission direction, and therefore also to variations in the color locus of the component. Furthermore, high acquisition costs for the equipment used to precisely meter the potting compound and the wear on this equipment caused by the abrasiveness of the luminescence conversion material or phosphor have a not-to-be-neglected impact on production costs.

WO 01/65613 A1 discloses a method of making semiconductor components in which a luminescence conversion element is applied directly to the semiconductor body. This has the advantage that phosphors can be applied to the semiconductor body uniformly and in a well-defined quantity. The semiconductor chip can thus be made to yield a homogeneous color impression.

In that method, the semiconductor body is mounted on a carrier, is provided with contacts, and is coated with a luminescence conversion element. The coating is done either by means of a suitable suspension containing a solvent that escapes after application, or by coating with an adhesion promoter to which the phosphor is subsequently applied.

It is one object of the present invention to supply an improved method of making LED chips provided with a luminescence conversion material which in particular can be carried out in a simple and low-cost manner. A further object is to specify an LED chip that is provided with a luminescence conversion material and can be made in a technically simple and low-cost manner.

These objects are achieved by means of a method according to Claims 1 and Claim 2, respectively, and by means of an LED chip according to Claim 15. Advantageous embodiments and preferred refinements of the method and the LED chip are the subject matter of the dependent claims.

In the method, a layer composite is prepared that includes an LED layer sequence for a multiplicity of LED chips and comprises on a main surface at least one electrical contact surface for each LED chip, for electrically connecting said LED chip.

According to a first method, a layer of adhesion promoter is applied to the main surface of the layer composite and is thereafter selectively removed from at least portions of the contact surfaces. A further method step includes applying at least one phosphor to the main surface of the layer composite.

In a second method, the luminescence conversion material is applied to the main surface of the layer composite. In addition, the luminescence conversion material is selectively removed from at least portions of the contact surfaces.

In the methods, the luminescence conversion material is applied in a technically simple manner substantially simultaneously to a multiplicity of LED chips of a common layer composite, for example a complete wafer. Since the adhesion promoter or luminescence conversion material is selectively removed from at least portions of the contact surfaces, the LED chips made in accordance with the method are used in the same way as conventional LED chips, and in particular are also electrically contacted.

The exposure of the contact surfaces occurs substantially in regions that overlap laterally with the contact surfaces, so that the luminescence conversion material or the phosphor, which is applied in a well-defined, preferably thin layer, is substantially unaffected by the exposure of the contact surfaces. The contact surfaces are at least partially exposed by the selective removal of the adhesion promoter or the luminescence conversion material said adhesion promoter or luminescence conversion material being removed substantially only in the region of the contact surfaces.

The selective removal of the adhesion promoter in accordance with the first method is particularly advantageous in cases where the adhesion promoter is easier to remove than a luminescence conversion material. Moreover, in this way the contact surfaces are advantageously removed prior to the application of the phosphor, which therefore cannot be negatively affected by the method step of exposure.

In the application of luminescence conversion material according to the second method, an adhesion promoter is advantageously first applied, followed by at least one phosphor. Alternatively, an adhesive luminescence conversion material is preferably applied in a single method stop, making it possible to eliminate one method step.

The layer composite preferably comprises an epitaxially grown semiconductor layer sequence applied to a carrier. The semiconductor layer sequence advantageously either is grown epitaxially directly on the carrier or is applied to the carrier after being epitaxially grown.

The LED layer sequence of the layer composite need not necessarily be configured in one piece, but instead, in an advantageous embodiment of the method, is singulated into a multiplicity of LED chips, which are applied to a common carrier and thereby held in a layer composite. The luminescence conversion material can thus be applied to lateral surfaces of the LED chips. Alternatively, this is advantageously achieved at least in part by providing an LED layer sequence configured in one piece with trenches along dicing lines for cleaving the multiplicity of LED chips from the main surface.

The phosphor or luminescence conversion material is preferably applied by means of doctor blades. In this way, the material concerned can be applied broadly in a thin, uniform layer over the entire main surface of the layer composite in a technically simple and low-cost manner.

Alternatively, the phosphor or luminescence conversion material is applied by immersion in a converter material containing the phosphor or luminescence conversion material or a precursor thereof. Advantageously, this is a particularly low-cost process that also permits the broad application of thin, uniform layers of material.

In a further alternative process, the phosphor of luminescence conversion material is preferably applied by means of an electrostatic powder spraying process. This is suitable for the especially finely meterable and uniform application of a phosphor or of a luminescence conversion material supplied in solid form.

In an advantageous embodiment of the second method, the luminescence conversion material is applied by means of a powder painting process, in which, in particular, it is first applied via an electrostatic powder spraying process and is heated to bring about adhesion to the main surface. The powder painting process is suitable for especially finely meterable and uniform application of the luminescence conversion material.

In a further alternative process, the phosphor or luminescence conversion material is advantageously applied by atomizing a converter material that contains the phosphor or luminescence conversion material or a precursor thereof. This is a technically simple and low-cost process by means of which the material concerned can be uniformly applied.

Particularly preferably, the atomization takes place with the use of volatile propellants and additionally or alternatively with the use of an air current.

In a further embodiment of the method, the application of the phosphor or luminescence conversion material by atomization takes place more than once. Particularly good meterability of the application process can be achieved by this means. A plurality of layers comprising different phosphors or a plurality of layers of different luminescence conversion materials can be applied in this way.

After application, the adhesion promoter or the luminescence conversion material is preferably selectively removed by means of a lithographic process. Advantageously used for this purpose is a photolithographic process in which a mask is produced by applying and structuring a layer of mask material. This is, advantageously, a standard process commonly used in optoelectronics to structure semiconductor layers or contact-metal surfaces.

Alternatively, the lithographic process includes the use of a prefabricated mask that is applied to the main surface. This eliminates the need to create a mask by applying and structuring a layer of mask material.

As an alternative to the lithographic process, the adhesion promoter or luminescence conversion material is removed using laser radiation, i.e. the material concerned is selectively ablated by the action of laser radiation.

The inventive LED chip has at least one electrical contact surface on a main surface provided with a luminescence conversion material. In a region that overlaps laterally with the contact surface, the luminescence conversion material comprises a clearance such that the electrical contact surface is exposed, i.e. at least a portion of the electrical contact surface is free of the luminescence conversion material.

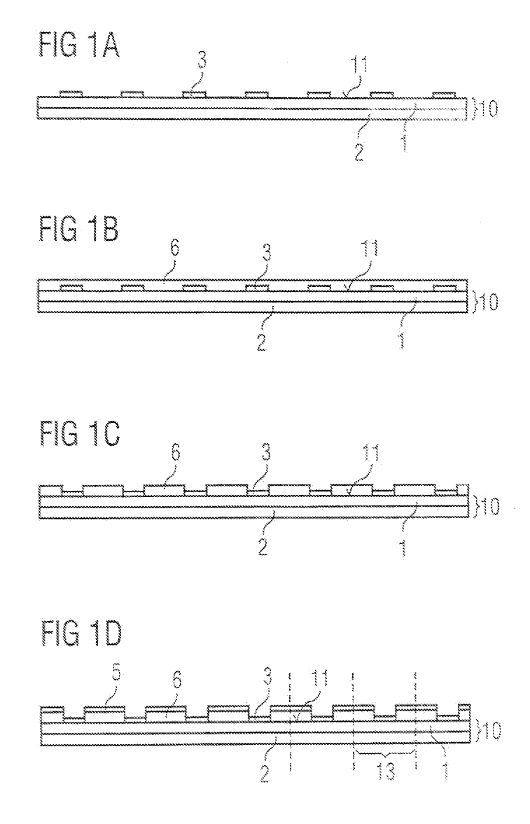

Further advantages, preferred embodiments and refinements of the method and of the LED chip will become apparent from the exemplary embodiments explicated below in conjunction with FIGS. 1a to 6d. Therein:

FIGS. 1a to 1d are schematic sectional views of a layer composite in different method stages of a first exemplary embodiment of a method according to the invention,

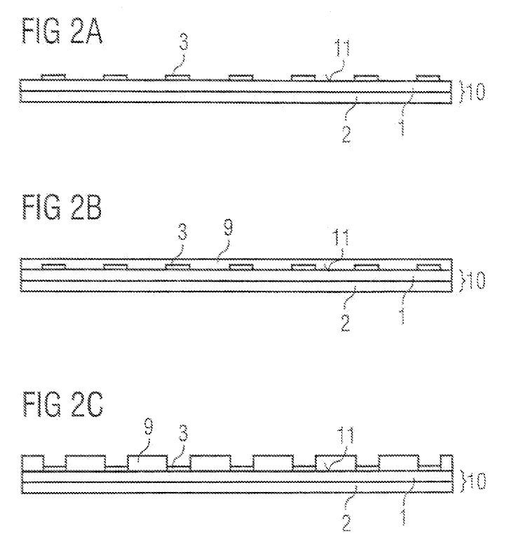

FIGS. 2a to 2c arc schematic sectional views of a layer composite in different method stages of a second exemplary embodiment of a method according to the invention,

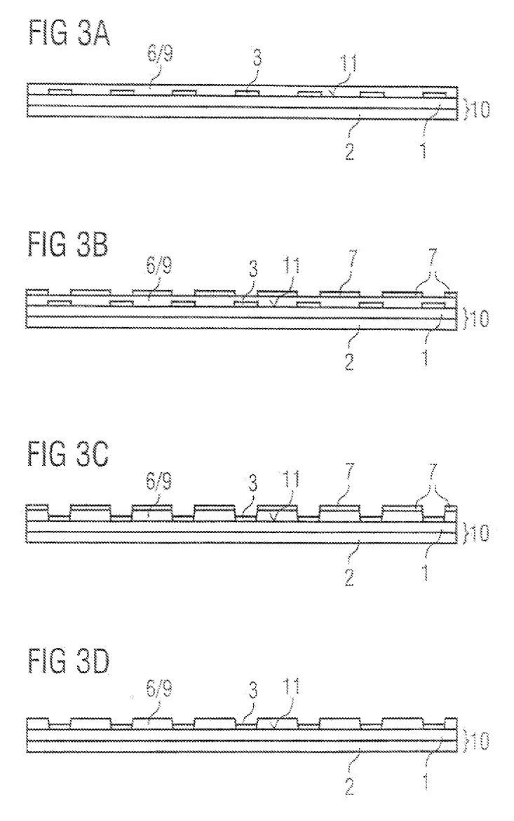

FIGS. 3a to 3d are schematic sectional views of a layer composite in different method stages of a third exemplary embodiment of a method according to the invention,

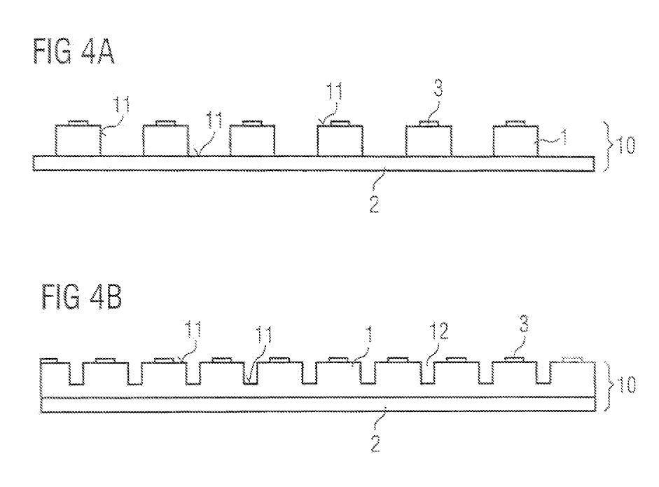

FIGS. 4a and 4b are schematic sectional views of various exemplary embodiments of a layer composite,

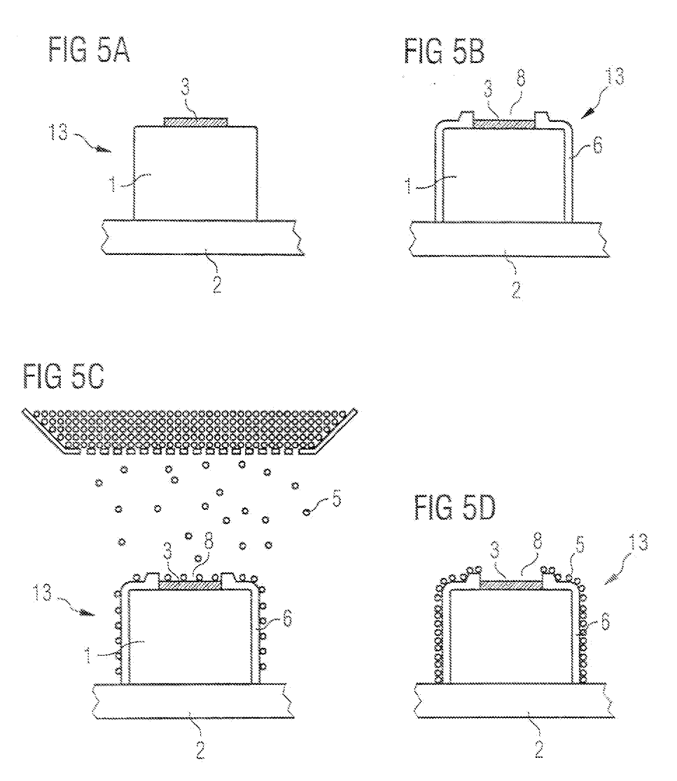

FIGS. 5a to 5d are schematic sectional views of a subregion of a layer composite in different method stages of a fourth exemplary embodiment of a method according to the invention, and

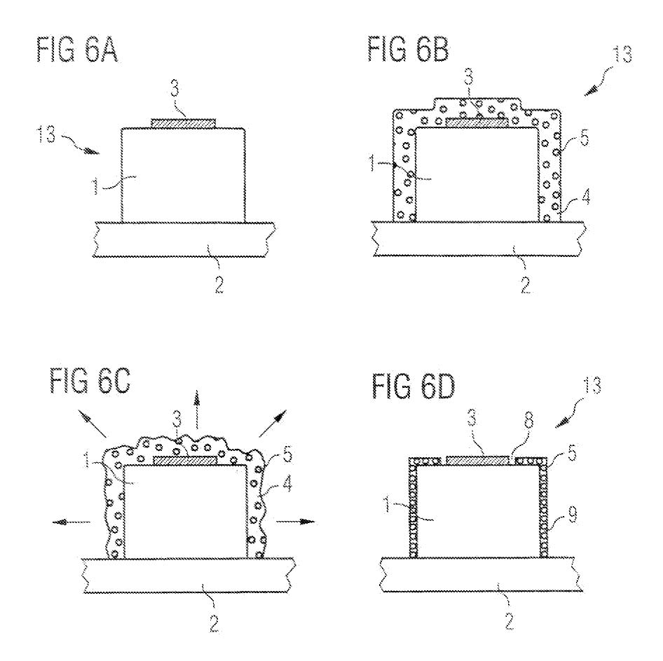

FIGS. 6a to 6d are schematic sectional views of a subregion of a layer composite in different method stages of a fifth exemplary embodiment of a method according to the invention.

In the exemplary embodiment and figures, like or like-acting elements are provided with the same respective reference numerals. The elements depicted and their size relationships to one another are not to be considered true to scale. Rather, some details of the figures are depicted as exaggeratedly large for the sake of better understanding.

FIG. 1a shows a layer composite 10 comprising an LED layer sequence 1 applied to a carrier 2. The LED layer sequence 1 is for example an epitaxially grown semiconductor layer sequence intended for a multiplicity of an LED chips. The carrier 2 is for example a growth substrate on which the LED layer sequence is grown.

Alternatively, the layer composite 10 is a thin-film layer composite, the LED layer sequence 1 of which was grown on a separate growth substrate, subsequently detached from it, and applied, for example soldered, to the carrier 2, which is for example a carrier substrate made of a semiconductor material. Disposed between the LED layer sequence 1 and the carrier 2 is for example a reflective electrical contact structure (not shown), at which an electromagnetic radiation generated in the LED layer sequence 1 is reflected and by means of which the LED layer sequence is for example electrically conductively connected to the carrier 2.

The LED layer sequence 1 is based for example on nitride compound semiconductors, i.e. it preferably contains AlₓIn_{y}Ga_{1-x-y}N, where 0≦x≦1, 0≦y≦1 and x+y≦1. This material need not necessarily have a composition that is mathematically exactly that of the above formula. Rather, it can include one or more dopants and additional constituents that do not substantially alter the physical properties of the material. For the sake of simplicity, the above formula includes only the essential components of the crystal lattice (Al In, Ga, N), even though these may be partially replaced by minuscule amounts of other substances.

When exposed to a current, the LED layer sequence emits for example an electromagnetic radiation in a blue or ultraviolet wavelength range. It can for example comprise a conventional pn junction, a double heterostructure, a single quantum well structure (SQW structure) or a multiple quantum well structure (MQW structure). Such structures are known to the skilled person and thus will not be elaborated on herein.

An adhesion promoter 6 is applied to the main surface 11 of layer composite 10 (see FIG. 1b). The adhesion promoter 6 is transparent to an electromagnetic radiation generable by the LED layer sequence 1 and is preferably resistant to aging under the effect of that radiation. For example, an adhesion promoter is used that is based on silicone and is resistant to aging by UV radiation. A suitable candidate for this purpose is, for example, tacky silicone, such as the adhesion promoter supplied by the Wacker company under the product designation SLM 647. The adhesion promoter can be cured either for about 24 hours at room temperature or for about one hour at approximately 100° C.

The adhesion promoter 6 is then selectively removed from the electrical contact surfaces 3, so that these are at least partially exposed and can each be electrically contacted (see FIG. 1c).

In a further method step, at least one phosphor 5 is applied to the main surface 11 of the layer composite 10. The phosphor 5 itself is not adhesive, so it remains adhering substantially only to those locations where adhesion promoter 6 is present. Where appropriate, a gas jet can be used to clean phosphor 5 that is not sticking to the adhesion promoter 6 off the contact surfaces 3.

The layer composite 10 thus provided with a luminescence conversion material composed for example of the adhesion promoter 6 and the phosphor 5, can then be singulated into separate LED chips 13 along dicing lines (indicated by broken lines in FIG. 1d), this operation being performed for example by sawing and/or scribing and breaking.

Suitable for use as phosphors are, for example, inorganic phosphors such as rare earths, particularly containing Ce or Tb, doped garnets, preferably having the basic structure A₃B₅O₁₂, or organic phosphors such as perylene phosphors. Additional suitable phosphors are listed, for example, in WO 98/12757 and in WO 01/65613 A1, whose content in this regard is hereby incorporated by reference.

Illustrated in FIG. 2a is a layer composite 10, which may, for example, be configured in the manner of the layer composite 10 described previously with reference to FIG. 1a. An adhesive luminescence conversion material 9 containing at least one phosphor is applied directly thereto (see FIG. 2b). The percent by weight of phosphor present in the luminescence conversion material 9 is at least 50%, preferably 60 wt. % or more. By way of comparison, it may be noted that potting compounds with phosphor admixtures typically contain between 5 and 20 wt. % phosphors.

Basically ail the converters known for use with LEDs are suitable for application to the surfaces of the layer composite. Examples of such phosphors and phosphor mixtures that are suitable for use as converters are:

chlorosilicates, such as those disclosed, for example, in DE 10036940 and the prior art described therein,
orthosilicates, sulfides, thiometals and vanadates, such as those disclosed, for example, in WO 2000/33390 and the prior art described therein,
aluminates, oxides, halophosphates, such as those disclosed, for example, in U.S. Pat. No. 6,616,862 and the prior art described therein,
nitrides, sions and sialons, such as those disclosed, for example, in DE 10147040 and the prior art described therein, and
rare-earth garnets, such as YAG:Ce and the alkaline earth elements, such as those disclosed, for example, in US 2004-062699 and the prior art described therein. The content of the above-cited documents with regard to the composition and nature of the phosphors described therein and methods for making them is hereby expressly incorporated by reference.

There are essentially no limitations on the emission colors that can be obtained with the LED chips or the luminescence conversion material.

The luminescence conversion material 9 is present for example as a mass of suitable viscosity that contains the phosphor, an adhesion promoter (e.g. silicone-based) and any other desired substances, such as solvents, for example. It is applied for example by means of doctor blades, the luminescence conversion material 9 being pushed through the holes in a screen or stencil (not shown) by means of a rubber lip or a metal bar. The stencil has for example a thickness of 125 μm and is provided with holes that have for example a quadrangular cross section with a side length of about 350 μm. Alternatively, the stencil is about 300 μm thick and has for example quadrangular holes with an edge length of about 300 μm.

As an alternative to doctor blading, the layer composite 10 with the main surface 11 can also be dipped in a suitable converter material. Doctor blading and immersion are not only suitable for applying luminescence conversion material or converter material, but can also be used for example to apply adhesion promoter (see the exemplary embodiment described m connection with FIGS. 1a to 1d).

Other possible processes for applying luminescence conversion material, converter material, phosphors or adhesion promoters are, for example, an electrostatic powder spraying process, a powder painting process or atomization, which is also discussed in detail hereinafter. Spraying or dripping is theoretically also possible.

FIG. 2c shows the layer composite 10 after a method step in which the luminescence conversion material 9 is selectively removed from the contact surfaces 3.

The selective removal of luminescence conversion material or adhesion promoter is effected for example by means of a lithographic process, as explained hereinafter with reference to FIGS. 3a to 3d. FIG. 3a depicts a layer composite 10 provided with a continuous luminescence conversion material layer 9 or adhesive material layer 6. To selectively remove the luminescence conversion material 9 or adhesion promoter 6, a mask 7 is used (see FIG. 3b), through which the material in question is selectively removed, for example by etching with a suitable etchant (see FIG. 3c).

If the luminescence conversion material contains silicone, it can be etched for example by means of dry chlorine, acetic acid and/or fluoride.

The mask 7 can be produced for example in a photolithographic process by applying and structuring a layer of mask material. It is alternatively possible to use a prefabricated mask 7, which is applied to the main surface 11 of the layer composite 10. In both cases, the mask or mask material is removed after the selective removal of the luminescence conversion material 9 or the adhesion promoter 6 (see FIG. 3d).

The LED layer sequence need not necessarily be one-piece, for example in the form of a wafer configured in one piece, but instead can be singulated to yield a multiplicity of LED chips prior to the application of the adhesion promoter or luminescence conversion material, in which case the individual parts of the LED layer sequence are applied to a common carrier 2 and held by it in a common layer composite 10 (see FIG. 4a). If a layer composite 10 prepared in this way is used to make the LED chips provided with the luminescence conversion material, then the LED chips so fabricated will have luminescence conversion material not only on main surfaces extending parallel to the contact surfaces 3, but also on lateral surfaces that do not extend parallel to a main direction of extension of the contact surfaces.

Alternatively, the LED layer sequence 1 can also be provided with trenches 12 before being provided with a luminescence conversion material, so that the adhesion promoter, phosphor and/or luminescence conversion material is/are also applied in these trenches 12. The trenches are produced for example by sawing.

FIGS. 5a to 6d each illustrate a detail of a layer composite 10 in which the LED layer sequence 1 is already singulated to yield a multiplicity of LED chips 13. FIG. 5b illustrates a portion of the LED layer sequence 1 to which a thin layer of adhesion promoter 6 is applied. The adhesion promoter 6 is selectively removed in the region of the electrical contact surface 3, such that the layer of adhesion promoter 6 has a clearance 8 in which the electrical contact layer 3 is exposed.

FIG. 5c shows the application of a phosphor 5 by means of an electrostatic powder spraying process. For this purpose, the phosphor 5 is present for example as a powder with an average particle size of about 10 μm. The powder particles are negatively or positively charged, depending on the method used, and the layer composite 10, which includes carrier 2 and LED layer sequence 1, is grounded, so that the charged powder particles are electrostatically attracted. The phosphor 5 durably adheres only to the adhesion promoter 6 (see FIG. 5b).

Alternatively, the phosphor is applied for example by atomization with the aid of volatile propellants or in a stream of gas, the gas used being for example an inert gas or air.

In place of a lithographic process and the application of a mask, the selective removal of the adhesion promoter 6 or the luminescence conversion material 9 can theoretically be performed by means of a material ablation process involving laser irradiation. The use of a mask for this purpose is not absolutely necessary, but is possible. The material in question is selectively removed by the local thermal action of the laser beam. To speed up the process, it is possible to split the laser beam by means of beam splitters such as prisms, so that for example four laser beams can be supplied with only one laser source, thereby speeding up production and making it possible for it to be performed at lower cost.

FIGS. 6a to 6d illustrate the application of a luminescence conversion material 9 by means of a suspension 4. Here, a thin layer of a suspension 4 of a phosphor 5 is applied to the LED layer sequence 1 (see FIG. 6b). The suspension 4 contains, for example, butyl acetate as a solvent. The adhesion promoter used can be for example, a copolyacrylate, such as for example Perenol F45 (Henkel KGaA). The phosphor 5 is present in this suspension in a concentration of more than 40% by volume. The suspension layer 4 can be produced by being sprayed or dripped on.

In addition, rheological additives and wetting agents can also be added to the suspension 4 to obtain the most homogeneous layer possible.

A leveling agent with deaerating properties can be used to alter the surface tension of the adhesion promoter and thereby improve adhesion. A silicone-free leveling agent is preferably used for this purpose.

Following application, the layer composite with the carrier 2 and the LED layer sequence 1 is dried, during which process the solvent evaporates, as illustrated in FIG. 1c. Substantially all that remains on the semiconductor body is the phosphor 5 with the adhesion promoter, as depicted in FIG. 1d, the luminescence conversion material 9 so applied having been selectively removed from electrical contact surface 3 and from around contact surface 3, i.e., the layer of luminescence conversion material 9 is provided with a clearance 8 such that electrical contact surface 3 is exposed. The LED chip 13 can then be singulated from the layer composite 10, either by removing the carrier 2 from the LED layer sequence 1 or by cleavage between the parts of the LED layer sequence.

A plurality of different phosphors can be applied by the method, for example in successive layers. Likewise, plural layers of different luminescence conversion materials can be applied one on top of the other. A further option is to apply additional layers of adhesion promoter to applied phosphor and to apply at least one additional phosphor to each of those layers.

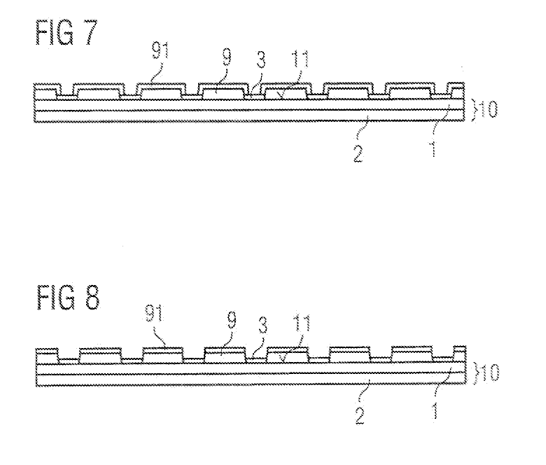

It is also possible to apply at least one protective layer 91 on top of the luminescence conversion material, whereby the luminescence conversion material can be partially or completely protected against moisture right on the chip (see FIGS. 7 and 8). Partial protection can be achieved by covering subareas of the luminescence conversion material with a protective layer 91, as shown by way of example in FIG. 8. Complete protection against moisture can be achieved correspondingly by completely encapsulating the luminescence conversion material with a protective layer 91, which is particularly preferred. An example of this is illustrated in FIG. 7.

The protective layer 91 usefully comprises a water-tight material. A suitable material for this purpose is, for example, silicon dioxide, which for example can be the sole constituent of the protective layer.

The protective layer 91 is applied for example with foil coverage and is then partially removed, for example by lithography, to expose covered electrical contact surfaces. It is, of course, possible to use alternative methods to apply and/or remove the protective layer 91; in particular, all of the methods described hereinabove for applying and/or partially removing the luminescence conversion material may in principle be used analogously.

Applying a protective layer 91 also makes it possible to achieve long life even with phosphors that are unstable or susceptible to aging under exposure to moisture. This is a consideration particularly with regard to the direct application to LED chips of luminescence conversion material in which no matrix material is used, or much less matrix material than is used for example in potting LED chips in a potting compound with a phosphor admixture.

The invention is not limited to the exemplary embodiments by the description of it with reference thereto. For example, the electrical contact surfaces 3 can be prevented a priori from being covered with adhesion promoter or luminescence conversion material. This can be accomplished for example using a suitable stencil, such as for example a needle card, which is pressed against the main surface of the layer composite and thereby at least partially seals the electrical contact surfaces with its needles. The invention encompasses any novel feature and any combination of disclosed features, including in particular any combination of features recited in the claims, even if that feature or combination itself is not explicitly mentioned in the claims or exemplary embodiments.

1. A method of making LED chips provided with a luminescence conversion material containing at least one phosphor, comprising the steps of:
preparing a layer composite that includes an LED layer sequence intended for a multiplicity of LED chips and comprising on a main surface at least one electrical contact surface for each said LED chip, for electrically connecting the respective said LED chips;
applying a layer of adhesion promoter to said main surface of said layer composite;
selectively removing said adhesion promoter from at least portions of said contact surfaces; and
applying at least one phosphor to said main surface of said layer composite.

2. A method of making LED chips provided with a luminescence conversion material containing at least one phosphor, comprising the steps of:
preparing a layer composite that includes an LED layer sequence intended for a multiplicity of LED chips and comprising on a main surface at least one electrical contact surface for each said LED chip, for electrically connecting the respective said LED chips;
applying a luminescence conversion material to said main surface of said layer composite; and
selectively removing said luminescence conversion material from at least portions of said contact surfaces.

3. The method as in claim 1, wherein said LED layer sequence comprises an epitaxially grown semiconductor layer sequence applied to a carrier.

4. The method as in claim 1, wherein said phosphor or said luminescence conversion material is applied by doctor blading.

5. The method as in claim 1, wherein said phosphor or said luminescence conversion material is applied by immersion in a converter material containing said phosphor or said luminescence conversion material or a precursor thereof.

6. The method as in claim 1, wherein said phosphor or said luminescence conversion material is applied by means of an electrostatic powder spraying process.

7. The method as in claim 2, wherein said luminescence conversion material is applied by means of a powder painting process.

8. The method as in claim 1, wherein said phosphor or said luminescence conversion material is applied by atomizing a converter material containing said phosphor or said luminescence conversion material or a precursor thereof.

9. The method as in claim 8, wherein said atomization takes place with the use of volatile propellants and/or a current of air.

10. The method as in claim 8, wherein the application of said phosphor or of said luminescence conversion material by atomization takes place more than once.

11. The method as in claim 1, wherein said adhesion promoter or said luminescence conversion material is removed by means of a lithographic process.

12. The method as in claim 11, wherein said adhesion promoter or said luminescence conversion material is removed by means of a photolithographic process.

13. The method as in claim 11, wherein said lithographic process includes the use of a prefabricated mask.

14. The method as in claim 1, wherein said adhesion promoter or said luminescence conversion material is removed with the use of laser radiation.

15. An LED chip comprising on a main surface at least one electrical contact surface, and wherein said main surface is provided with a luminescence conversion material, characterized in that said luminescence conversion material comprises a clearance such that said electrical contact surface is exposed.

16. The LED chip as in claim 15, characterized in that said luminescence conversion material is partially or completely covered with a protective layer.

17. The method as in claim 2, wherein said LED layer sequence comprises an epitaxially grown semiconductor layer sequence applied to a carrier.

18. The method as in claim 2, wherein said phosphor or said luminescence conversion material is applied by doctor blading.

19. The method as in claim 2, wherein said phosphor or said luminescence conversion material is applied by immersion in a converter material containing said phosphor or said luminescence conversion material or a precursor thereof.

20. The method as in claim 2, wherein said phosphor or said luminescence conversion material is applied by means of an electrostatic powder spraying process.

21. The method as in claim 2, wherein said phosphor or said luminescence conversion material is applied by atomizing a converter material containing said phosphor or said luminescence conversion material or a precursor thereof.

22. The method as in claim 21, wherein said atomization takes place with the use of volatile propellants and/or a current of air.

23. The method as in claim 2, wherein said adhesion promoter or said luminescence conversion material is removed by means of a lithographic process.

24. The method as in claim 2, wherein said adhesion promoter or said luminescence conversion material is removed with the use of laser radiation.
